(19) United States
(12) Patent Application Publication
(10) Pub. No.: US 2003/0142741 A1
(43) Pub. Date: Jul. 31, 2003

(54) Modulation by phase and time shift keying and method of using the same

(75) Inventor: Clinton S. Hartmann, Dallas, TX (US)

Correspondence Address: HITT GAINES P.C., P.O. BOX 832570, RICHARDSON, TX, 75083, US

(73) Assignee: RF SAW Components, Incorporated, Dallas, TX

(21) Appl. No.: 10/062,833

(22) Filed: Jan. 30, 2002

(51) Int. Cl. H03K 7/04

(52) U.S. Cl. 375/239

(57) ABSTRACT

The present invention provides for a propagated signal modulated by phase and time shift keying and a method of using the same. In one embodiment the propagated signal includes: (1) a period of time spanned by a pulse, the period of time divided into a group of time slots, each of the time slots having a unique phase/time position; and (2) the pulse encoding a data element by the phase/time position.

### TECHNICAL FIELD OF THE INVENTION

The present invention is directed, in general, to a propagated signal and, more specifically, to a propagated signal modulated by phase and time shift modulation and a method of using the same.

### BACKGROUND OF THE INVENTION

Electronic data transmission requires some form of signal modulation that encodes data onto an information bearing signal so that the signal can be propagated over a transmitting medium and demodulated to unambiguously recover the data originally encoded. Modulation can be viewed as the process by which digital data, voice, music, and other “intelligence” is added to radio waves produced by a transmitter so that the intelligence is in a form suitable for propagation. Modulation can also be viewed as the addition of information to an electronic or optical signal carrier in a manner that permits the encoded data to be reliably decoded. Modulation can be applied to direct current (mainly by turning it on and off), to alternating current, and to optical signals. One can even view blanket waving as a form of modulation used in smoke signal transmission (the carrier being a steady stream of smoke). Morse code, invented for telegraphy and still used in amateur radio, is a method of modulation that uses a binary (two-state) digital code similar to the code used by modern computers.

Modulation implies the occupancy of bandwidth, a precious resource the conservation of which is of increasing importance to all but most particularly to those in the data and information transmission business. Bandwidth conservation requirements has increased the pressure on users to make the most efficient use of bandwidth as technology permits. One method to increase bandwidth efficiency is to utilize transmission techniques that maximize the amount of data or information that is transmitted over a limited period of time. One way to increase the amount of data transmitted over a limited time period is to utilize those modulation methods that maximize encoded data transmitted over the allocated time period.

A number of methods are now being used to modulate electronic signals to transmit digital data. For most radio and telecommunication uses, the carrier being modulated is alternating current (AC) within a given range of frequencies. Some of the more common modulation methods include: amplitude modulation (AM), in which the amplitude of the carrier signal is varied over time; frequency modulation (FM), in which the frequency of the carrier signal is varied; and phase modulation (PM), where the phase of the carrier signal is varied over time. These are all classified as continuous wave modulation methods in order to distinguish them from the pulse code modulation (PCM) methods used to encode digital and analog information in a binary way. There are also more complex forms of modulation, such as phase shift keying (PSK) and quadrature amplitude modulation (QAM), as well as methods to modulate optical signals by applying an electromagnetic current that varies the intensity of a laser beam.

Depending on the intended use, all the foregoing methods of modulation permit a relatively reliable transmission of electronic data over a distance. However, as more and more bandwidth is being used because of a constantly increasing amount of data to be transmitted, there exists a need for even more efficient data transmission capability. As more information is digitized, even more pressure is exerted on transmission systems and bandwidth demand. Although improved equipment and technology is of some help in resolving the problems caused by an increased demand for bandwidth, other solutions are also required.

One way to partially resolve the problem of limited bandwidth is to encode more data on the carrier. If the amount of data transferred over a limited period of time is increased, the infrastructure and equipment required to support such infrastructure can be significantly reduced.

Thus, what is required in the art are new and novel methods to modulate electronic signals that increase the amount of digital data that can be transferred and the rate at which such transfer can occur.

### SUMMARY OF THE INVENTION

To address the above-discussed deficiencies of the prior art, the present invention provides for a propagated signal modulated by phase and time shift keying and a method of using the same. In one embodiment the propagated signal includes: (1) a period of time spanned by a pulse, the period of time divided into a group of time slots, each of the time slots having a unique phase/time position; and (2) the pulse encoding a data element by the phase/time position.

The present invention therefore introduces the broad concept of encoding data by locating pulses by both phase position and time position within a group of slots of a propagated signal. This new and novel method of encoding a signal provides a dramatic increase in the amount of data that a propagated signal can carry over a specific period of time as compared to that which could be carried using prior art encoding methods.

In one embodiment of the present invention the data element is coded and decoded by mapping. In another embodiment the time slots in a group are adjacent while in yet another embodiment the time slots in a group are not adjacent. In either case the encoded signal can be mapped and decoded at its termination point without any change in data being transmitted.

The invention is sufficiently versatile that in one embodiment the time slots within a group have a non-uniform spacing. Further versatility is demonstrated by the fact that another embodiment provides for more than one pulse to be located within a group of time slots.

This new invention permits a substantial amount of data to be encoded within a very short period of time. For example, in one embodiment of the present invention, a single group can encode data that is more than fifteen bits in length. Those of ordinary skill in the art will recognize that fifteen bits of data is substantial.

A particularly useful aspect of the invention provides for the group to be used to encode a variety of different types of data. In one embodiment of the invention the element of data encoded in a group is selected from a group of different types of data consisting of a header; an error detection message; a synchronization element; and a data message. Those of ordinary skill in the pertinent art will recognize that most streams of data will most probably include all three different types of data groups.

In still another embodiment of the present invention a propagated signal consists of a plurality of the groups. In yet still another embodiment, the groups have differing numbers of time slots.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

For a more complete understanding of the present invention, reference is now made to the following descriptions taken in conjunction with the accompanying drawings, in which:

FIG. 1 illustrates a graph showing the allowable positions for a conventional prior art group of four pulses using digital pulse position modulation (PPM);

FIG. 2 illustrates a graph showing allowable pulse positions that are deliberately structured to have overlapping spacing significantly smaller than Tmin;

FIG. 3 illustrates a graph of an example of a signal with pulses separated by a slot width of Tmin/5 showing an attempted five-fold increase in data transmission over that shown in FIG. 1;

FIGS. 4A and 4B illustrate graphs showing implementation of an embodiment of the present invention with real and imaginary parts of overlapping pulses and an added phase shift of +90°; and

FIG. 5 illustrates a graph of an embodiment of the present invention using a phase increment other than 90° to demonstrate the substantially improved discrimination between a correct state and its neighboring states with allowable pulse spacings of Tmin/5 and using a 78.5° phase difference between adjacent allowed states.

### DETAILED DESCRIPTION

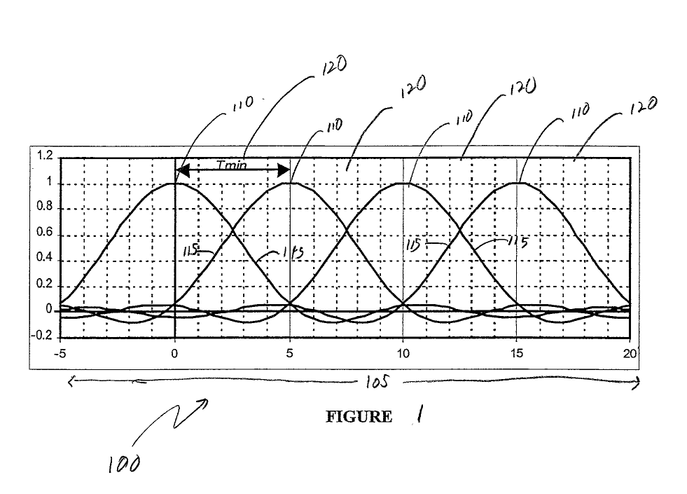

Referring initially to FIG. 1, illustrated is a graph 100 showing the allowable positions for a conventional prior art group 105 of four pulses 110 using digital pulse position modulation (PPM). The illustrated group can be viewed as four slots 120 with Tmin being the time separation between the allowable pulse 110 peak positions. In PPM only one of these pulses 110 in this group 105 is transmitted to avoid intersymbol interference with an adjacent or potentially adjacent pulse 110. If demodulation sampling is done at the four allowable peak positions, three of the samples will be essentially zero and the correct sample will have an amplitude of unity.

If sampling during demodulation is not properly synchronized to the peak positions, the amplitude for the “correct pulse” location will start decreasing while the amplitude at a neighboring location will become larger than zero. However, the signal can still be correctly demodulated since only one pulse 110 is transmitted and the correct position for the pulse 110 can be ascertained without much difficulty. If noise is also present in the system, the probability of incorrect demodulation will also be increased because of the timing error. However, if the timing error is small, the degradation is negligible and the signal can be demodulated. As a general rule, if the signal to noise ratio is sufficiently small, the signal can be successfully demodulated as long as the timing error is less than Tmin/2.

This ability to successfully distinguish between two possible positions of a single pulse 110 even when the pulses 110 are partially overlapped can be used to increase data density at the expense of signal to noise ratio sensitivity. This increase in data density is achieved by moving allowable pulse 110 positions closer together so that the skirt 115 of one allowable pulse 110 overlaps the skirts 115 of the neighboring pulse 110.

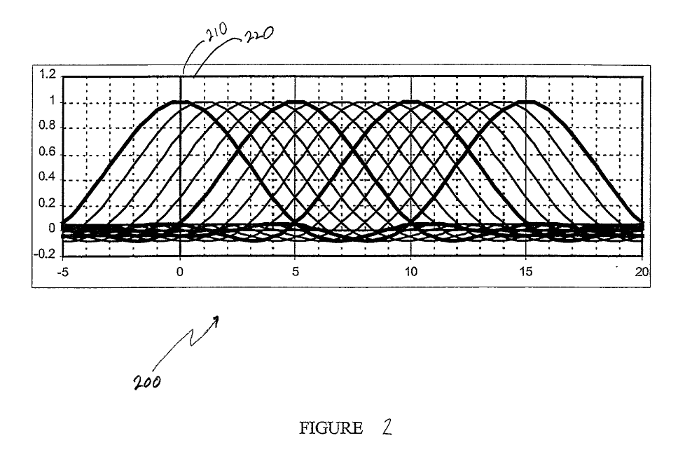

Turning now to FIG. 2, illustrated is a graph 200 showing allowable pulse positions 210 (one of which is marked) that are deliberately structured to have overlapping spacing significantly smaller than Tmin. In fact, the allowable spacing has been reduced to one unit as compared to the five units in FIG. 1 and each slot 220 has a width equal to Tmin/5, thus representing a potential five-fold increase in the number of states available to encode data. However, this method of increasing data density is rarely used because of the reduction in the detection margin available for distinguishing between neighboring pulse positions.

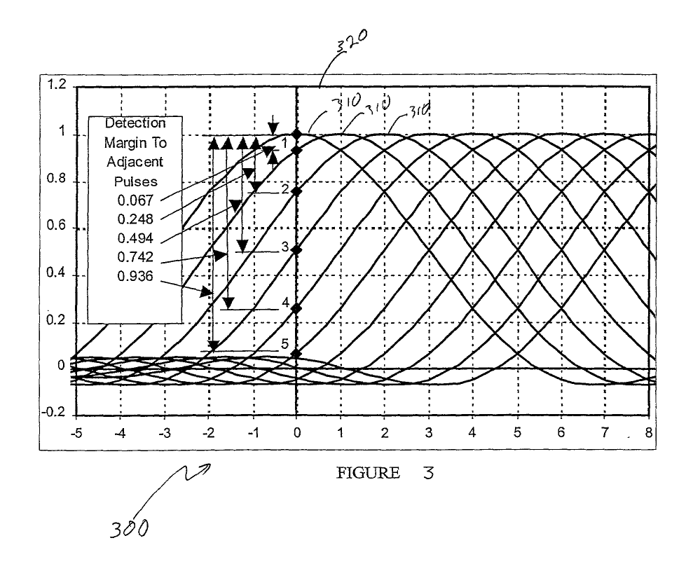

Turning to FIG. 3, illustrated is a graph 300 of an example of a signal with pulses 310 separated by a slot 320 width of Tmin/5 showing an attempted five-fold increase in data transmission over that shown in FIG. 1. The difficulty of demodulating such a signal using prior art methods is readily apparent because of the limited detection margin. To demodulate a signal with such strongly overlapping pulses 310, it would be necessary to sample the received signal at the peak locations of all possible pulse positions (i.e., at all integer locations on the horizontal axis). It is readily apparent that amplitude discrimination is particularly poor with respect to adjacent pulse positions, which discrimination problem will increase for the next adjacent pulse 310. The present invention provides a novel modulation format to overcome these modulation problems.

The present invention provides for modifying the allowable pulses so that each pulse not only has a different time position but also an added phase step between each adjacent pulse. For example, if a phase step of ±90° is added between each adjacent pulse, then the pulse at t =0 (time equals zero) may have a 0° phase, the pulse at t =1 will have ±90°, the pulse at t =2 will have ±180°, the pulse at t =3 will have ±270°, the pulse at t =4 will have ±360°, etc. This combination of simultaneous phase and time shifted modulation substantially improves the ability to discriminate between neighboring pulses.

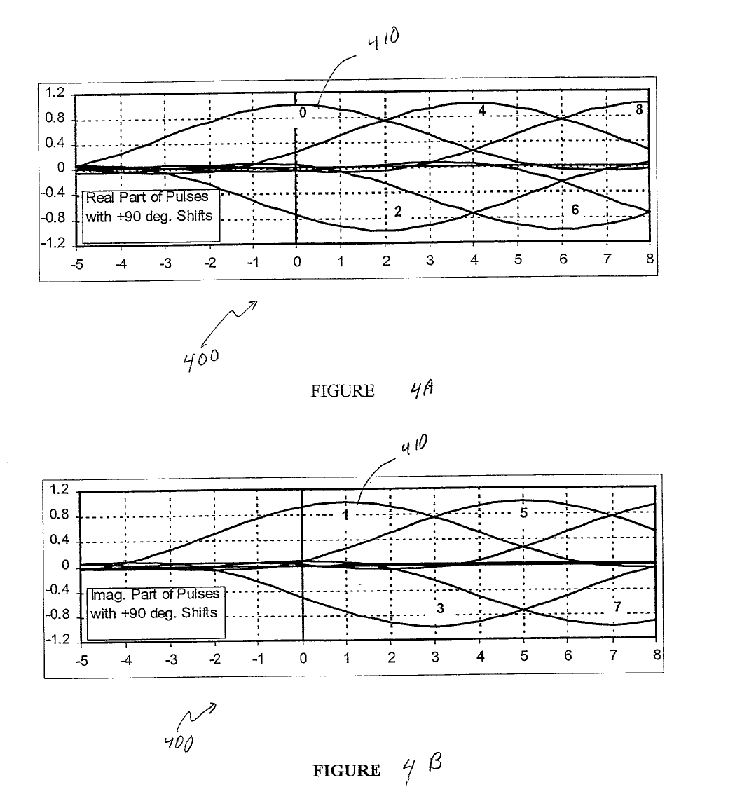

Turning now to FIGS. 4A and 4B, illustrated are graphs 400 showing implementation of an embodiment of the present invention showing the real and imaginary parts of overlapping pulses 410 and an added phase shift of +90°. Because phase multiples of 90° are used, the odd numbered pulses 410 (1, 3, 5, etc. ) have real parts equal to zero and the even numbered pulses 410 have imaginary parts equal to zero. To demodulate this signal, it is necessary to sample the real part of the received signal at the peak locations (t =0, 1, 2, etc.)as well as shifting the phase of the sampling signal from one time slot to the next such that it would agree with the expected phase of a pulse 410 if it should occur at that slot locations.

In general, a wide range of phase angles can be used all of which will be within the intended scope of the present invention. Many of these phase angle will give equal or better performance than the example illustrated in FIGS. 4A and 4B. For example, a stepping angle could vary around the 90° value by more than ±20° without significant degradation of performance when using slot separations of Tmin/5.

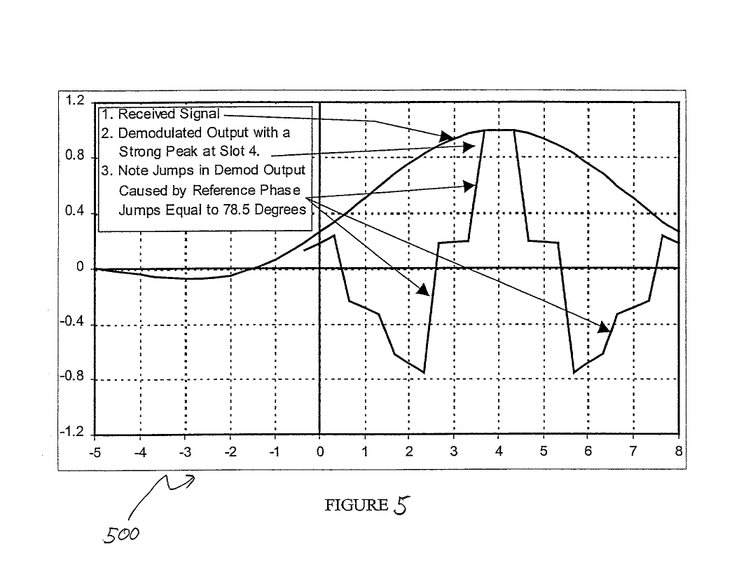

Turning now to FIG. 5, illustrated is a graph 500 of an embodiment of the present invention using a phase increment other than 90° to demonstrate the substantially improved discrimination between a correct state and its neighboring states with allowable pulse 510 spacings of Tmin/5 and using a 78.50° phase difference between adjacent allowed states. A phase increment other than 90° is shown to illustrate the substantially improved discrimination between the correct state and neighboring states for a wide variety of phase angles. FIG. 5 also illustrates the dramatic improvement in discrimination as compared to the identical allowed pulse spacing without phase shifts that was illustrated in FIG. 3. FIGS. 3 and 5 each have an identical five-fold improvement in the number of possible states when compared to the more conventional PPM with allowable pulse spacing of Tmin. But, without the phase shifts, the detection minimum margin is only 0.067 while, with the phase shifts, the detection margin to adjacent states is now 0.81, as shown in FIG. 5, which is close to conventional PPM that has a detection margin approaching unity.

Thus the present invention is best characterized by simultaneously shifting both the phase and the time location of a pulse communication signal in a known manner. By mapping the encoding shown above, the amount of data that can be sent and decoded is very substantial. In one embodiment of the invention more than fifteen bits of data can be encoded in a single group and, by mapping the codes used, reliably decoded. Mapping constitutes a predetermined arrangement or agreement whereby an encoded data message or signal has a specific meaning attributable to it that is ascertainable when the encoded data message or signal is decoded or demodulated. This arrangement or agreement can take the form of a protocol, such as an agreed upon table of codes, that assigns a reliable and ascertainable meaning to an encoded signal when it is decoded. The advantage of using the present invention to encode a data message is clear. A vast amount of information can be encoded on data elements within a propagated signal that permits the transfer of substantial data over a very short period of time, thus conserving bandwidth.

While the embodiment of the invention considered herein used uniformly spaced time shifts and uniformly spaced phase shifts, those of ordinary skill in the pertinent art will understand that non-uniform spacing of either the time shifts or phase shifts (or both) is well within the intended scope of the present invention. Similarly, groups can vary in the number of slots and/or in the number of occupied slots and still be within the scope of the present invention. Also, a single group can be defined such that it only has a fixed number of occupied slots or, alternatively, it might allow for a varying number of occupied slots. Also, a single data message could include more than one type of group (for example the header might be one type of group, the actual data a second type of group, and an error detection/correction word might be of a third type). As will be recognized by those of ordinary skill in the pertinent art, all of these variants as well as others are well within the intended scope of the present invention.

The present invention also provides several embodiments of methods for propagating a signal. In one such embodiment the method calls for designating a period of time spanned by a pulse, with the period of time divided into a group of time slots such that each of the time slots has a unique phase/time position. The method then provides for causing the pulse to encode a data element by the phase/time position. The invention includes several other embodiments of methods for propagating a signal. Sufficient detail has been set forth herein to enable one of ordinary skill in the pertinent art to understand and practice the various embodiments of such methods.

Although the present invention has been described in detail, those skilled in the art should understand that they can make various changes, substitutions and alterations herein without departing from the spirit and scope of the invention in its broadest form.

What is claimed is:

1. A propagated signal, comprising:
a period of time spanned by a pulse, said period of time divided into a group of time slots, each of said time slots having a unique phase/time position; and
said pulse encoding a data element by said phase/time position.

2. The propagated signal as recited in claim 1 wherein said data element is ascertainable by mapping.

3. The propagated signal as recited in claim 1 wherein said time slots in said group are adjacent.

4. The propagated signal as recited in claim 1 wherein said time slots in said group are not adjacent.

5. The propagated signal as recited in claim 1 wherein said time slots have a non-uniform spacing.

6. The propagated signal as recited in claim 1 wherein more than one pulse is located within said group of time slots.

7. The propagated signal as recited in claim 1 wherein said group encodes data that is more than fifteen bits long.

8. The propagated signal as recited in claim 1 wherein said element of data is selected from the group consisting of:
a header;
an error detection message;
a synchronization element; and
a data message.

9. The propagated signal as recited in claim 8 further comprising a plurality of said groups.

10. The propagated signal as recited in claim 8 wherein said groups have differing numbers of time slots.

11. A method of propagating a signal, comprising:
designating a period of time spanned by a pulse, said period of time divided into a group of time slots, each of said time slots having a unique phase/time position; and
causing said pulse to encode a data element by said phase/time position.

12. The method as recited in claim 11 wherein said data is ascertainable by mapping.

13. The method as recited in claim 11 wherein said time slots in said group are adjacent.

14. The method as recited in claim 11 wherein said time slots in said group are not adjacent.

15. The method as recited in claim 11 wherein said time slots have a non-uniform spacing.

16. The method as recited in claim 11 wherein more than one pulse is located within said group of time slots.

17. The method as recited in claim 11 wherein said group encodes data that is more than fifteen bits long.

18. The propagated signal as recited in claim 11 wherein said element of data is selected from the group consisting of:
a header;
an error detection message;
a synchronization element; and
a data message.

19. The method as recited in claim 11 further comprising designating a plurality of said groups.

20. The propagated signal as recited in claim 18 wherein said groups have differing numbers of time slots.
